(19) United States
(12) Patent Application Publication
(10) Pub. No.: US 2026/0198034 A1
(43) Pub. Date: Jul. 9, 2026

(54) Semiconducting graphene platform

(71) Applicant: Georgia Tech Research Corporation, Atlanta, GA (US)

(72) Inventor: Walter A. De Heer, Atlanta, GA (US)

(21) Appl. No.: 19/132,724

(22) PCT Filed: Apr. 7, 2023
(86) PCT No.: PCT/US2023/017922

§ 371 Date: May 23, 2025

Related U.S. Application Data
(60) Provisional application No. 63/438,941, filed on Jan. 13, 2023.
(60) Provisional application No. 63/439,709, filed on Jan. 18, 2023.

(51) Int. Cl. H10D 30/43; H10D 62/81; H10D 64/66

(52) U.S. Cl. CPC H10D 30/43; H10D 62/81; H10D 64/66

(57) ABSTRACT

A semiconducting circuit (10) includes a silicon carbide crystal (100), a semiconducting graphene layer (101), a dielectric layer (102), at least one work function enhanced gate (108) and at least one electrical conductor (113). The silicon carbide crystal (100) has a crystal surface. The semiconducting graphene layer (101) is disposed on the crystal surface. The dielectric layer (102) is disposed on the semiconducting graphene layer (101). The at least one work function enhanced gate (108) is disposed on the dielectric layer (102) on a side opposite from the semiconducting graphene layer (101). The at least one electrical conductor (113) is in electrical communication with the at least one work function enhanced gate (108).

### CROSS-REFERENCE TO RELATED APPLICATION(S)

This application claims the benefit of U.S. Provisional Patent Application Ser. Nos. 63/438,941, filed Jan. 13, 2023 and 63/439,709, filed Jan. 18, 2023, the entirety of each of which is hereby incorporated herein by reference.

### BACKGROUND OF THE INVENTION

### 1. Field of the Invention

The present invention relates to thin film electronic devices and, more specifically, to a system for making thin film graphitic devices.

### 2. Description of the Prior Art

In modern microelectronics integrated circuit technology, a silicon wafer is lithographically patterned to accommodate a large number of interconnected electronic components (field effect transistors, resistors, capacitors, etc.). The technology relies on the semiconducting properties of silicon and on the lithographic patterning methods employed. Increasing the density of electronic components and reducing the power consumption per component are two of the most important objectives in the microelectronics industry, which has driven the steady reduction in the size of the components in the past decades. However, miniaturization of silicon-based electronics will reach an ultimate limit in the near future, primarily because of limitations imposed by the material properties of silicon, and doped silicon, at the nanoscale.

To sustain the current trend in microelectronics beyond the limits imposed by silicon-based microelectronics technologies, alternative technologies need to be developed. Requirements for such an alternative technology include: smaller feature sizes than feasible with silicon-based microelectronics, more energy-efficient electronics strategies, and production processes that allow large-scale integration, preferably using lithographic patterning methods related to those used in silicon-based microelectronics fabrication.

Several alternatives to silicon-based electronics have been proposed. However, none of the proposed alternatives fulfills all three of the above-listed requirements. For example, graphene is considered an attractive alternative, which has been actively pursued for the past two decades. However the absence of a band gap in pristine graphene and difficulties in chemically functionalizing graphene in order to convert it into a semiconductor with suitable electronic properties have been met with limited success.

Two dimensional semiconductors also are attractive alternatives. However, despite many attempts world-wide, the properties of these materials are not up the required standards. It has been proposed that mobilities of currently investigated 2D semiconductors cannot surpass that of silicon for fundamental reasons.

Another promising development has been the use of the epitaxial graphene buffer layer to produce field effect transistors having graphene leads that are seamlessly connected to semiconducting graphene. Unfortunately this form of semiconducting graphene has a mobility that is too low for many commercial applications.

Because of these disadvantages, graphene, semiconducting graphene and are not currently being used in conventional 2D semiconductor commercial integrated electronic circuits.

Recently an improved form of semiconducting epitaxial graphene was discovered, having significantly improved properties over prior methods to produce semiconducting epitaxial graphene. However this material cannot be processed using conventional microelectronic methods without significantly damaging the material and thereby compromising its advantageous properties, which include very large mobilities at room temperature and 0.6 eV bandgap.

Therefore, there is a need for an electronic device technology that surpasses silicon technology.

### SUMMARY OF THE INVENTION

The disadvantages of the prior are overcome by the present inventions which, in one aspect is a semiconducting circuit that includes a silicon carbide crystal, a semiconducting graphene layer, a dielectric layer, at least one work function enhanced gate and at least one electrical conductor. The silicon carbide crystal has a crystal surface. The semiconducting graphene layer is disposed on the crystal surface. The dielectric layer is disposed on the semiconducting graphene layer. The at least one work function enhanced gate is disposed on the dielectric layer on a side opposite from the semiconducting graphene layer. The at least one electrical conductor is in electrical communication with the at least one work function enhanced gate.

In another aspect, the invention is a method of making a semiconducting circuit, in which a semiconducting graphene layer is formed on a selected crystal face of a silicon carbide crystal. A dielectric layer is applied to the semiconducting graphene layer. At least one work function enhanced gate is applied to the dielectric layer. The at least one work function enhanced gate is coupled to an electrical conductor.

The invention includes a method of making nanoscopic semiconducting epitaxial graphene (SEG) electronic devices without lithographically patterning the SEG itself. The invention produces seamlessly interconnected semiconducting epitaxial graphene devices and can be used to replicate complementary metal oxide semiconductor (CMOS) circuits with significantly improved properties.

Integrated electronics based on ultra-thin semiconducting graphene film (UTGF) have several advantages over prior art, these include: large-scale integration is possible using standard microelectronics lithography methods; metals are not necessarily used to interconnect the devices so that metal-to-graphite contact resistances can be avoided and power dissipation at the contacts can be greatly reduced or even eliminated. Integrated electronic device structures whose operation relies on quantum interference effects can be constructed. Also, feature sizes as small as 1 nm scale are possible and limited only by the lithography methods employed.

These and other aspects of the invention will become apparent from the following description of the preferred embodiments taken in conjunction with the following drawings. As would be obvious to one skilled in the art, many variations and modifications of the invention may be effected without departing from the spirit and scope of the novel concepts of the disclosure.

### BRIEF DESCRIPTION OF THE FIGURES OF THE DRAWINGS

FIG. 1A is an elevational view schematic diagram of a representative embodiment of a semiconducting graphene platform.

FIG. 1B is a top plan view schematic diagram of an embodiment of a semiconducting graphene platform with two top layers removed.

FIG. 2 is a schematic diagram showing effects of WEG work function on a SEG.

FIG. 3 is a schematic diagram showing the effects of applying a potential to WEGs on a SEG.

FIG. 4 is a schematic diagram of a system of WEG elements configured as a transistor.

FIG. 5 is a top plan view schematic diagram of P-channel SEGFET.

FIG. 6 is an elevational view of an N-channel semiconducting epigraphene field effect transistor.

FIGS. 7A-7C are schematic diagrams of a CSEG equivalent of a MOSFET inverter.

FIGS. 8A-8C are schematic diagrams of a CSEG equivalent of a CMOS NAND gate.

FIGS. 9A-9C are schematic diagrams of a simplified CSEG equivalent of a CMOS NAND gate.

FIGS. 10A-10C are schematic diagrams of a non-volatile electronic memory bit.

FIGS. 11A-11B are schematic diagrams of a system having contacts to the SEG layer.

FIGS. 12A-12B are schematic diagrams of a system configured as an energy filter.

FIG. 13A is a schematic diagram of a field effect transistor with an SEG channel.

FIG. 13B is a graph showing transfer characteristics (I_{ds}-V_{gs}) at bias voltage of 0, 1 and 2 V for the device shown in FIG. 13A.

FIG. 13C is a graph showing transfer characteristic curve of the device at V_{ds}=1 V and corresponding logarithmic plot for the device shown in FIG. 13A.

### DETAILED DESCRIPTION

A preferred embodiment of the invention is now described in detail. Referring to the drawings, like numbers indicate like parts throughout the views. Unless otherwise specifically indicated in the disclosure that follows, the drawings are not necessarily drawn to scale. The present disclosure should in no way be limited to the exemplary implementations and techniques illustrated in the drawings and described below. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.”

U.S. Pat. Nos. 7,015,142, 7,327,000, 8,173,095, 8,460,764, 9,018,101 and 9,171,907 are incorporated herein by reference for the purpose of disclosing the generation and patterning of graphene, graphitic structures and graphene transistors.

Epigraphene is graphene that grows atomically aligned on silicon carbide (SiC) crystal surfaces. Millimeter scale atomically flat SiC terraces are covered with an epigraphene layer that is covalently bonded to the SiC surface. When well annealed, this epigraphene buffer layer is a two-dimensional semiconductor (SEG) with a 0.6 eV bandgap and at room temperature mobility larger than 3100 cm²V-1s-1, greatly exceeding all current 2D monolayer semiconductors. Alumina top-gated SEG field-effect transistor, (SEGFET) with an on-to-off ratio of 104, already suitable for digital electronics, can be significantly improved with boron nitride dielectrics under development. Hydrogen intercalation reversibly converts SEG into a high-mobility freestanding graphene monolayer that can be seamlessly integrated with SEG. Centimeter scale mean free paths are observed in the edge state of this graphene monolayer, by far the largest room temperature electronic mean free path observed in any material.

The invention uses semiconducting epitaxial graphene (SEG) to produce a graphene electronics platform that mimics CMOS electronics. It uses work function enhanced gates (WEGs), to modulate the charge densities of a 2D sheet of SEG. This is done without patterning the SEG directly. The SEG bandgap is 6 eV. Its mobility exceeds 4000 cm²V-1s-1 at room temperature, more than a factor of 10 better than any other 2D semiconductor, and it is a fully microelectronics compatible electronics grade silicon carbide crystal. The work function of a metal is the minimum thermodynamic work needed to remove an electron from a metal. The work function is a characteristic of the surface of the metal, which can be characteristic of a selected crystal face of the metal.

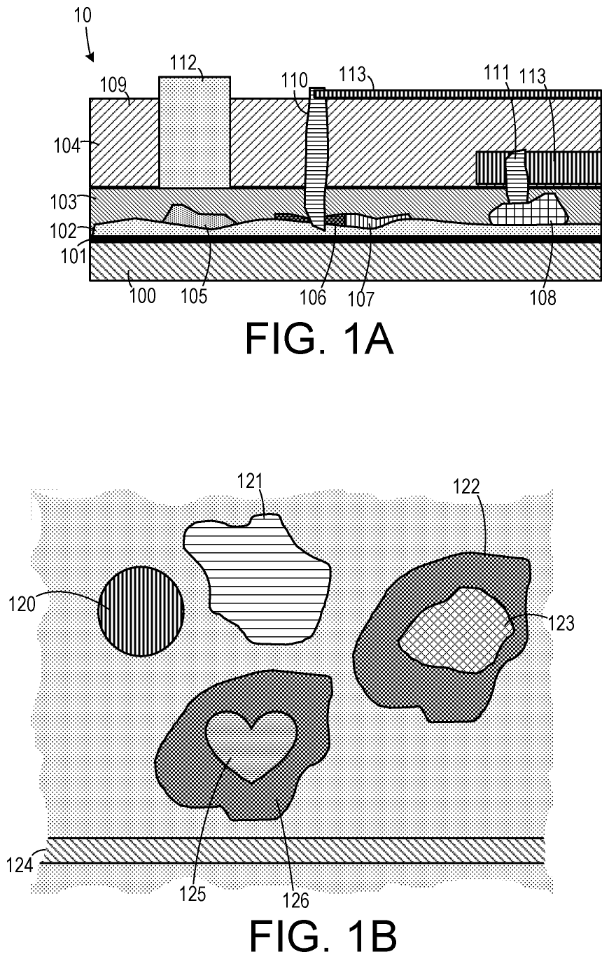

As shown in FIG. 1A, one embodiment of a generalized semiconducting graphene platform 10 includes a silicon carbide crystal surface 100 that is covered with a semiconducting graphene (SEG) film 101. The semiconducting graphene (SEG) film 101 can be made, for example, by annealing a silicon carbide crystal at a high temperature to produce an atomically flat surface on the silicon terminated surface of hexagonal silicon carbide, which is chemically bonded to the graphene layer 101. This transforms the graphene layer into an SEG film 101. A dielectric film 102 is deposited on the SEG film 101, which can be done using, for example, atomic layer deposition (ALD) or one of many other methods to produce dielectric films known to the art. The dielectric film 102 may be flat or, in some embodiments, it may be patterned so as to have a varying thickness. On top of the dielectric film 102, work function enhanced gates (WEGs) 105 106 107 108 are deposited. A WEG is an object that is made out of a material (such as a metal, a semiconductor or any material that has a work function) that is deposited on the dielectric layer 102. On top of the WEG structures 105 106 107 108 on the dielectric film 102, non-conducting layers are deposited 103 104 and are used to support interconnects 113 connected to the WEG structures 105 106 107 108 using vias, 110, 111, which are coupled to the WEG structures 105 106 107 108.

Also, a contact 112 can be inductively coupled to a WEG 105, which is beneath it, A charge can be induced on a WEG 105 either capacitively or by injecting a charge by the process of tunneling, which can occur when a sufficient potential is applied to the contact 112. The charge will remain on the WEG 105 after the potential is removed from the contact 112. The charge on the WEG 105 can also be altered by applying subsequent potentials to the Contact 112.

As shown in FIG. 1B (a top plan view with layer 102 and layer 104 removed), the WEGs 120 121 123 124 and 125 can have any shape or size and may include voids 126. They may be connected to others or they may be isolated from others. It should be noted that no specific shapes or sizes of the WEGs are implied. In typical embodiments, they can range in overall size from 0.5 nm to 10 cm. Also, in certain embodiments, the dielectric layer 102 may include a single material or it may include a layered material. For example, in certain embodiments, dielectric layer 102 may be covered with a layer of another material in order to affect the interface states of the WEGs.

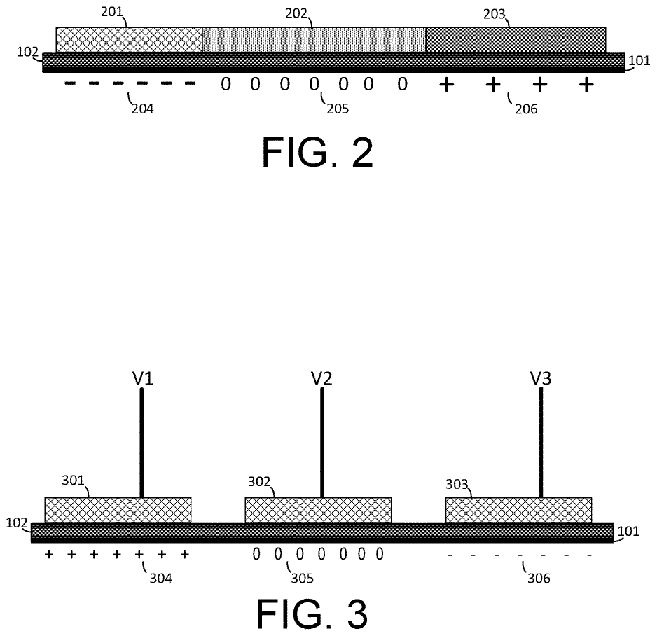

The three possible effects of an uncharged WEG 201 202 203 on an uncharged SEG film 101 are demonstrated in FIG. 2. A WEG 201 202 203 will primarily affect an area of the SEG film 101 that is directly under the WEG 201 202 203. In general if the work function of a WEG 201 is smaller than the electron affinity of the SEG 101, then a negative charge 204 will be induced in the SEG film 101. This essentially causes the SEG film 101 to become equivalently locally N-doped. If the work function of a WEG 203 is larger than the work function of the SEG then a positive charge 206 will be induced in the SEG 101, will become equivalently locally P-doped. If the work function of a WEG 202 is in between these values, then the SEG will remain equivalently undoped 205 and insulating, Variations to the specific action the WEG can vary and may also depend on the properties of the interface between the WEG and the dielectric 102. However, in general, the WEG will affect the charge state of the SEG mostly in the area directly beneath the WEG. These properties do not depend on whether the WEGs are in electrical contact with each other and, for specific applications, it may be advantageous to have the WEGs in contact with each other.

As shown in FIG. 3, when the sum of the work function of the WEG 301 and the voltage V1 is smaller than the work function of SEG 101, the SEG 101 will be positively charged 304. When the sum of the electron affinity of the WEG 303 and the voltage V3 is smaller than the work function of SEG 101, then the SEG 101 will be negatively charged 306. If the sum of the work function of the WEG 302 and V2 is between the work function and the electron affinity of the SEG 101, the SEG 101 will remain uncharged 305. The magnitude of the charge depends on the thickness and the dielectric constant of the dielectric 102. This example shows that 2-dimensional charge profiles can the imposed on the SEG film 101. Since the electrical conductivity is the magnitude product of the charge density and the mobility means that conducting paths can be defined, manipulated and turned on and off with external voltages.

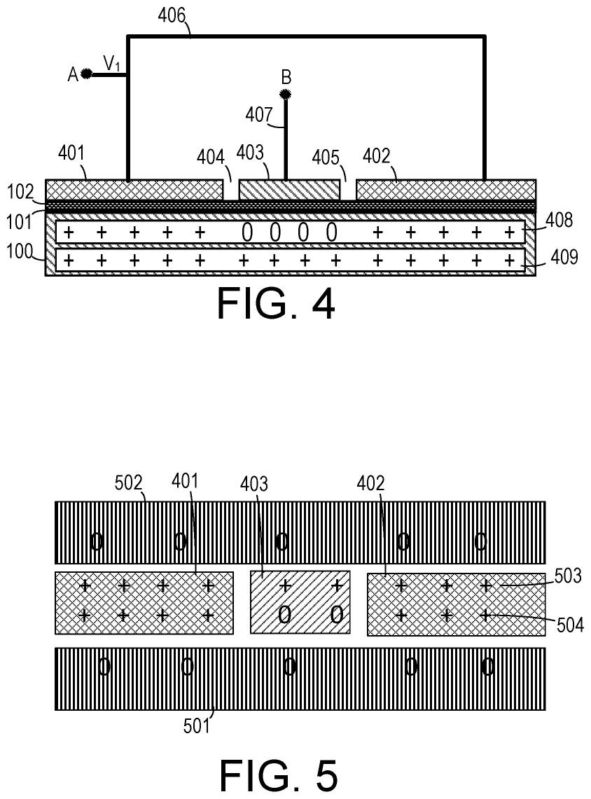

A cross section of a system of WEG elements configured as a P-channel semiconducting epigraphene field effect transistor (P-channel SEGFET) is shown in FIG. 4. The transistor includes three WEGs, 401 402 403, that are separate by gaps, 404 405. WEG 401 and WEG 402 are of the same material and they are electrically connected together by a wire 406. A potential V1 is applied to wire 406 to ensure that the SEG layer 101 beneath it is positively charged. WEG 403 is also connected to a wire 407 and the same potential V1 is applied to it. However WEG 403 is made of a different material that has a larger work function than WEG 401 and WEG 402, such that when voltage V1 is applied to it as well, then a charge is induced beneath the SEG 101, as indicated in 408. In this configuration the uncharged region in the SEG 101 is non-conducting, so that there is no conducting path for the positive electric charges to follow and the device is in an OFF mode. When the potential of WEG 403 is sufficiently increased, then the area under SEG 403 also becomes positively charged (as represented in item 409) so that there is now a continuous conducting path from left to right for the positive charges to follow and, thus, the device is in an ON mode. Therefore the device in shown in FIG. 4 functions as a P channel FET.

One practical example based on the design of FIG. 4 can employ a commercial semi insulating SiC crystal substrate (100), on which a semiconducting graphene layer 101 is grown. A 5 nm thick boron nitride layer 102 is deposited on the SEG. Two gold films about 50 nm by 100 nm 401 and 402 and one aluminum film, about 50 nm by 100 nm 407 are deposited on the boron nitride layer 102. The work function of aluminum is 4.24 eV so that it will p-dope the graphene while the work function of gold is 5.54 eV so that it will n-dope graphene. Likewise, the band gap of SEG is 0.6 eV and approximated centered on the work function of graphene which is 4.6 eV.

A top view of the configuration of WEGs that make a P-channel SEGFET is show in FIG. 5. A voltage is applied to WEG 501 and WEG 502 such that they do not induce a charge on the SEG layer in regions located directly under them, which is therefore in its insulating state at those locations, A conducting path is defined from left to right when WEG 401, WEG 402 and WEG 403 are at the potentials that produce the ON mode, which is indicated with the row of + symbols 503. When the potential on WEG 403 is sufficiently increased, the SEG beneath it becomes charge neutral 504 and there is no conducting path from left to right, so the FET is in its OFF mode. This example shows the basic functioning of the WEG configurations to induce a pattern of conducting paths on the SEG and a method to open and close those paths by applying the proper potentials.

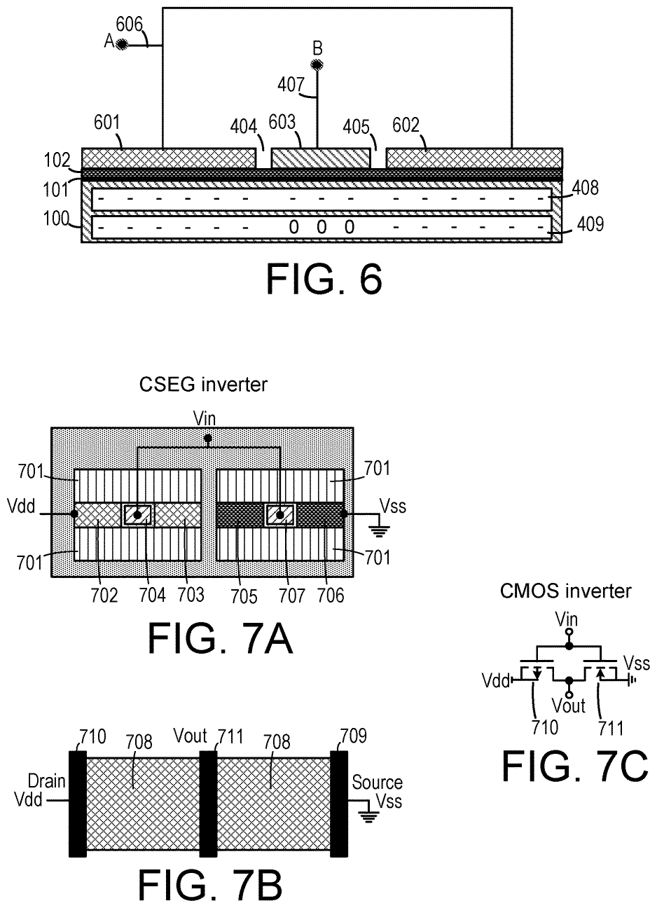

A cross section of a system of WEG elements configured as an N-channel semiconducting epigraphene field effect transistor (N-channel SEGFET) is shown in FIG. 6. The configuration is similar to the P-channel SEGFET, however the materials used for WEGs 601 602 and 603 are different than used for P-channel SEGFET. Here, WEG 603 is OFF at in a range of voltages and it turns ON when the potential on 407 is sufficiently increased.

A configuration of WEGs that functions as a complementary circuit that is analogous to MOSFET inverter is shown in FIGS. 7A-7C. The equivalent WEGFET is shown in FIG. 7C, which includes a P-channel SEGFET on the left in series with an N channel SEGFET on the right. The work function of WEG 701 is adjusted to that no charge is induced in the SEG layer at locations just beneath WEG 701. The appropriate work function is usually in the range of the work function of the SEG and the electron affinity of SEG, which is approximately in the range of 4.4 eV and 5 eV. WEGs 702 and 703 will have the work function that is about 0.3 eV smaller than that of WEG 701, and WEGs 705 and 706 have work functions that are about 0.3 eV larger than that of WEG 701. (However, these values may vary substantially for certain applications.) The configuration of the contacts on the SEG 101 is shown in FIG. 7B. For conventional complementary semiconducting graphene field effect, CSEG applications, this configuration can be the same for all logic gate structures and includes a conducting source contact 709, a conducting drain contact 708, and a conducting output contact 710. In one example, the horizontal length of WEG 703 and WEG 705 may be reduced or even eliminated altogether without altering the essential performance features of the device. Also, WEGs 701 702 and 703 in the P-channel WEGFET are all in electrical contact with each other as is required for conventional CMOS-type circuits, however there may be applications where they are isolated from each other.

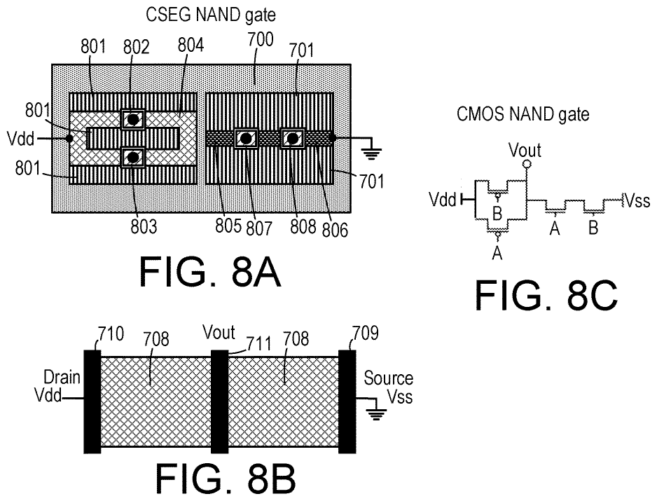

A CSEG equivalent of a CMOS NAND gate is shown in FIGS. 8A-8C. The structure of the SEG contacts can be the same as for the inverter shown above. The WEG structures on the dielectric layer 102, shown in FIG. 8A can be directly inferred from its schematic CMOS equivalent shown in FIG. 8C. In this example, there are 2 P-channel SEGFETs, 802 and 803 that are each similar to the P-channel SEGFET disclosed above (with reference to FIG. 7A), and they are connected in parallel by SEG 804. There are also 2 N-channel SEGFETs, 807 and 808, and they are connected in series by SEG 805, WEG 806 and WEG 809.

An important feature of WEG based 2D SEG electronics is its simplicity, where all of the nano-patterning is done on the dielectric layer. The dielectric layer is isolated from the SEG, which could be susceptible to damage from patterning processes. From an electronic point of view, the conducting patterns that are defined by the WEGs have electrostatic rather than physical boundaries, which are soft so that back scattering from nano-scopically patterned SEG as it is in nano-scopically patterned graphene, is completely eliminated. If the SEG layer is lithographically patterned in order to more securely isolate components, then a WEG can be placed over the patterned areas to render the area around the cut charge neutral so that these areas are isolated from the electric current paths.

In the design of SEG electronics, the functioning of PN junctions as possible current barriers tends to behave differently than in conventional semiconductor electronics. Band to band tunneling has been observed in carbon nanotubes for example, and the equivalent process, called Klein tunneling may occur in SEG, as is in graphene. However Klein tunneling can be used to reduce the thermally caused decreasing sub-threshold rise with increasing temperature, as has been observed in carbon nanotube, so that that the effect may also be used to reduce thermal effects in WEG based SEG electronics. The choice of materials that can used for the WEGs is very large, with work functions ranging from 2 eV to 6 eV, which is a much larger range than required for many applications.

Quantum mechanical confinement effects may play a significant role. In particular, 20 nm wide and narrower WEG defined paths may act like electronic wave guides for quantum mechanical charge carrier waves. Quantization of the energy levels on energy scales on the order of 25 meV and larger, which occurs for conducting channels that are narrower than 40 nm, can be utilized to substantially reduce sensitivity to thermal effects with in turn are at the root of large energy dissipation in CMOS technology. Purely quantum mechanical device structures involving Mach Zehnder-type interferometers may be feasible even at room temperature and these may play an important role is specific logic gate structures.

One consideration is the proper dielectrics to use. Standard alumina ALD may reduce the mobility too much in some applications. This is less of a concern with hafnium and boron nitride appears to work best in certain applications.

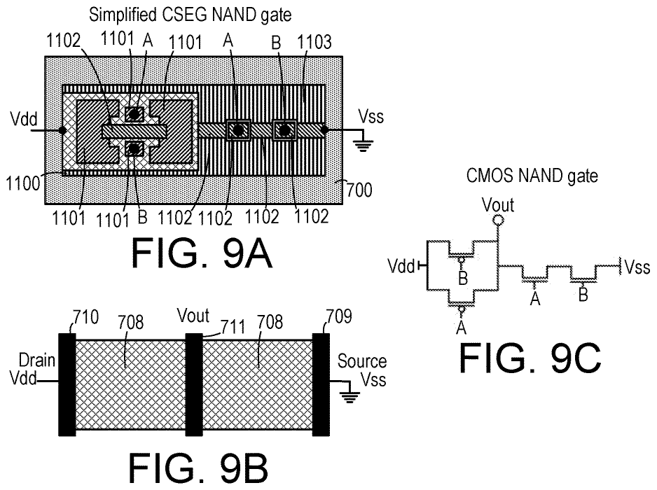

One example of a simplified version of a NAND gate is shown in FIGS. 9A-9C. In this example, WEG 1101 can include conducting material with the property that the Fermi level of the SBG beneath it will be in the band gap of the SEG, and therefore insulating, when a potential Vss is applied to it and the Fermi level of the SEG beneath it will be above the band gap of SEG when a potential Vdd is applied to it and therefore conducting. WEG 1102 can include conducting material with the property that the Fermi level of the SEG beneath it will be below the band gap of SEG, and therefore conducting, when a potential Vss is applied to it and the Fermi level of the SEG beneath it will be in the band gap of SEG when a potential Vdd is applied to it and therefore insulating. WEG 1103 can include conducting material with the property that the Fermi level of the SEG beneath it will be in the band gap of SEG, and therefore insulating, when a potential Vss is applied to it. One advantage of this simplified version is that only three materials are required. Also, the internal device interconnect between the two A terminals and the two B terminals be can be made on the same plane.

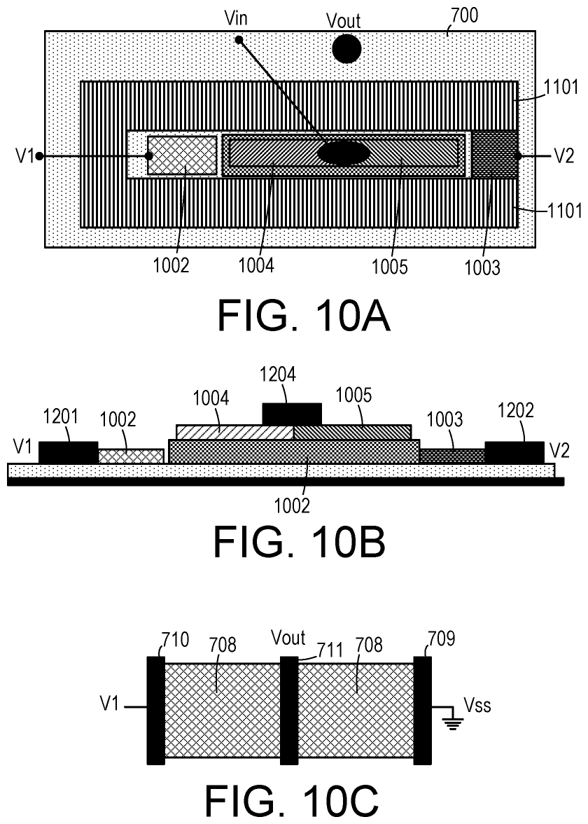

An embodiment including an example of a non-volatile electronic memory bit is shown in FIGS. 10A-10C. The supply voltage Vdd V1 is connected to WEG 1002 which involves a material that the Fermi level of the SEG beneath it will be below the SEG bandgap. WEG 1003 is connected to Vss V2 and includes a material such that the Fermi level of SEG is above the bandgap of SEG. WEG 1004 and WEG 1005 are in electrical contact with each other and involve materials such that when Vin equals Vdd, the SEG beneath WEG 1004 is above the band gap while at the same time the Fermi level of WEG 1005 is in the bandgap of SEG. In addition, when Vin is at the potential of Vss, the Fermi level of WEG 1004 is in the bandgap of SEG while at the same time the Fermi level of WEG 1005 is below the bandgap of SEG. WEG 1001 is in electrical contact with Vss and it is made of a material such that the Fermi of SEG beneath it is in the band gap of SEG, which ensures that the SEG surrounding the device is in its insulating state. This configuration ensures that when a potential Vdd is applied to Vin, that Vout will substantially be at the potential of Vss, while if the potential of Vin is that of Vss, the potential of Vout will substantially be that of Vdd. Note that the material of WEG 1002 may be chosen to be the same as that of WEG 1004 and that the material of WEG 1005 may be chosen to be the same as that of WEG 1003.

This example can also include a CSEG inverter with a composite WEG that includes WEG 1004 and WEG 1005 that are on top of WEG 1203. WEG 1203 can include a ferroelectric material, for example lead zirconate titanate (PZT). A ferroelectric like PZT is a material that can be electrically polarized by applying an electric field and that retains its electrical polarization after the electric field is removed. In this way, once electrically polarized there is a potential difference between the top and the bottom of WEG 1203, which, depending on the direction of the electric field (i.e. positive or negative), adds to or subtracts from the work function of WEG 1004 and WEG 1005. Thus, WEG 1203 functions much like a potential applied to a WEG. Therefore, WEG 1203, WEG 1004 and WEG 1005 can be adjusted so that in one direction of the polarization of the ferroelectric 1203, the resulting field is such that, when a potential V1 and V2 are applied, the SEG beneath WEG 1004 is in a conducting state, while the SEG beneath WEG 1005 is in a non-conducting state. On the other hand, if 1203 is polarized in the opposite direction, WEG 1004 is in a non-conducting state, while the SEG beneath WEG 1005 is in a conducting state. Therefore, the state of ferroelectric 1203 can be interrogated by measuring whether Vout is near V1 or if it is near V2. Applying a positive voltage between Vin and the SEG will polarize 1203 in positively, and applying a negative voltage between Vin and the SEG will polarize 1203 negatively.

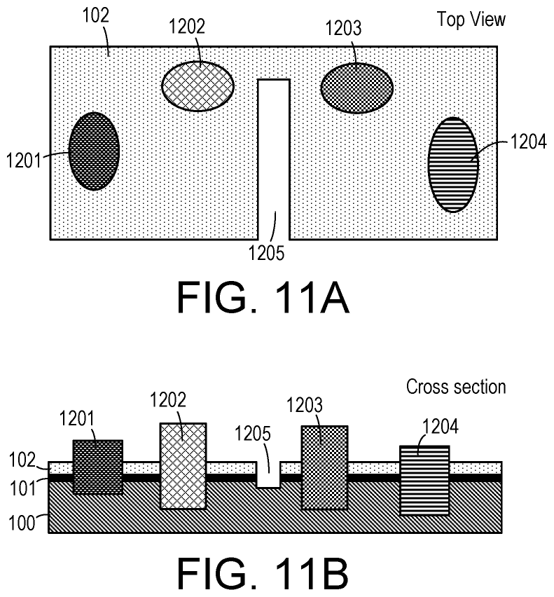

One embodiment of a system having contacts (1201 1202 1203 and 1204) to the SEG layer 102 is shown in FIGS. 11A-11B. The contacts 1201 1202 1203 and 1204 are produced after the insulating layer 102 has been deposited on the SEG layer 101 by perforating the insulation layer 102 and the SEG layer 101 and depositing conducting materials into the perforations. Applying contacts to the SEG 101 after the insulating layer 102 has been deposited has advantages, because this procedure will minimize the processing of the exposed SEG 101, which can affect its properties, for example, by producing charged areas on the surface that are known as charge puddles. Such charge puddles can deteriorate the performance of the devices.

The materials are chosen for their electrical properties and specifically to optimize the contact to the SEG layer 101 depending on the application. For example, it may be desired that source 709 and drain contacts 710 to the SEG layer have small resistances. However it may be desirable that output contacts 711 make a Schottky contact with the SEG layer, to optimize its performance, for example by minimizing the subthreshold rise of the device.

A region 1205 where the SEG layer is removed by lithographically cutting through the insulating layer 102 and through the SEG layer 101 may be required to insulate devices from each other and also to affect the electrical transport properties from the P side of the SEGFET device and the N side of the SEGFET device.

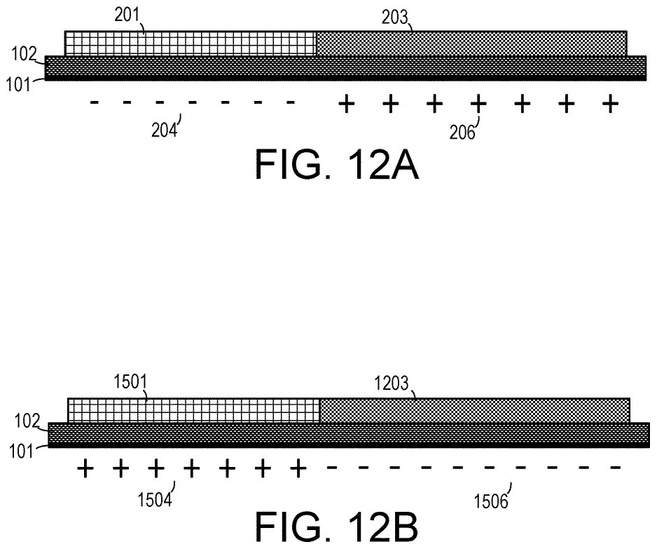

An embodiment configured as an energy filter is shown in FIGS. 12A and 12B. In this embodiment, WEG 201 is made of a material such that the it induces a negative charge 204 on the SEG 102 so that SEG beneath WEG 201 is slightly N doped, which means that the Fermi level there is slightly above the conduction band edge of SEG. WEG 203 can include a material such that the it induces a positive charge 206 on the SEG 102 so that SEG beneath WEG 203 is slightly P doped, which means that the Fermi level is slightly below the valence band edge of SEG. In this configuration, electrons passing from left to right through the device will be converted to holes by band to band tunneling. However since only electrons with energies those are above the conduction band edge will be transmitted through the device, and only holes that are below the valence band edge will be transmitted. The net result is that the device can serve as an energy filter that only allows charge carriers (i.e. electrons and holes) to be transmitted through the device within a narrow energy range. This configuration can be useful to minimize the subthreshold swing which is known to negatively impact the performance of field effect transistors at elevated temperatures.

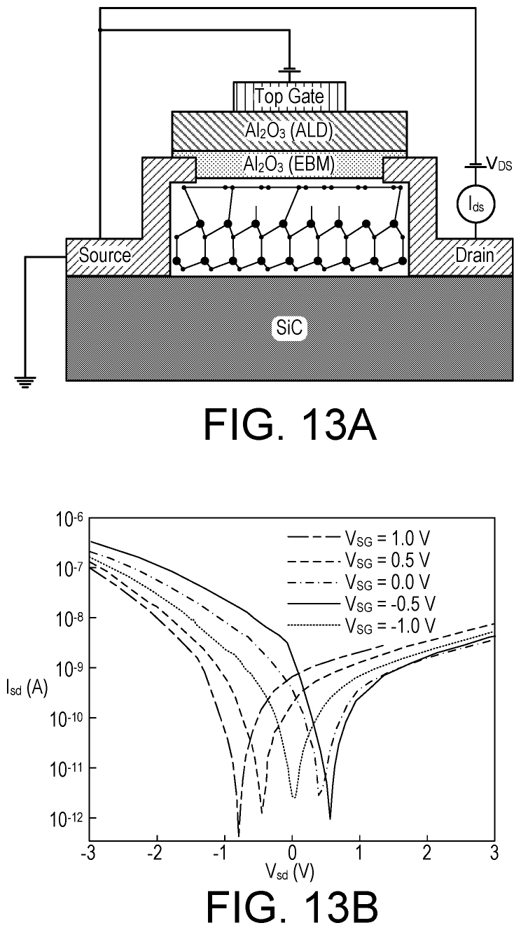

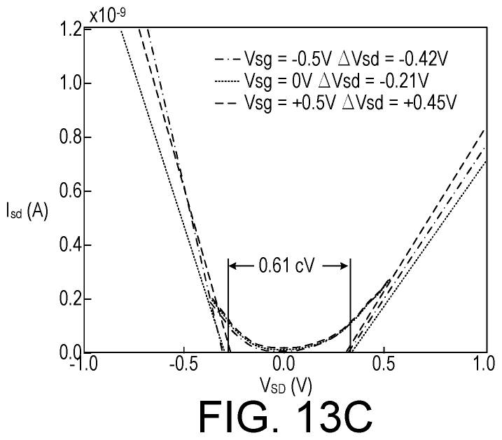

As shown in FIGS. 13A-13D, in one experimental embodiment, a field effect transistor was fabricated by conventional semiconductor techniques. Photoresist S1805 was spin-coated on the surface of SiC (0001) in order to be exposed by DMD laser direct writer (SVG-Micro 100). Then 10 nm Cr and 30 nm Au films were deposited and patterned on the substrate as source/drain electrodes using electron beam evaporation (EB-500), followed by the lift-off process. A thin metal film of aluminum (2 nm) was deposited on the SEG by e-beam evaporation first, followed by oxidation in the presence of residual O₂ during evaporation to serve as a seed layer for the top dielectric through subsequent ALD procedure. Finally, the top gate was fabricated by e-beam lithography and followed by a metal (Cr/Au) deposition and lift off. Electrical transport of devices was measured by a probe station (Lakeshore-Model TTPX) with semiconductor device analyzer (Keysight-B1500A) at room temperature.

The SG device mobility (μ) can be calculated as:

$$μ = \frac{Δ {I}_{sd}}{{ΔV}_{g}} \frac{L}{W} \frac{1}{{C}_{g} {V}_{sd}} \qquad ( 1 )$$

Where C_{g} is the gate capacitance per unit area; W (40 μm) and L (500 μm) are the width and length of the SG channel, respectively; V_{sd} is the source-drain voltage (1V).

The electrical properties of the SEG were measured by characterizing a fabricated top-gated monolayer SG field-effect transistor (more details can be seen in SI). A schematic drawing of a SEG field-effect transistor (FET) is shown in FIG. 13A. The transfer curves are shown in FIG. 13B, with V_{ds} of 0, 1.0 and 2.0 V. The device displayed unipolar conduction and typical p-type behavior. As V_{ds} increases, both Iₒₙ and I_{off} monotonically rise. As shown in FIG. 13C, the device exhibited excellent switching performance with an on/off ratio of ~10⁴ at V_{ds}=1 V and Iₒₙ=15 nA, which is similar to the FET made of 7-armchair graphene nanoribbons. The threshold voltage (V_{Th}) was −0.21 V which was extracted by extrapolating the linear regime of the transfer curve to the gate voltage axis. The subthreshold swing (SS) calculated using the expression SS=dV_{gs}/d(log I_{ds}) is 155 mV·dec⁻¹. There was a Schottky barrier (SB), which is noticeable from the non-linear behavior of I_{ds} at high V_{ds}.

Although specific advantages have been enumerated above, various embodiments may include some, none, or all of the enumerated advantages. Other technical advantages may become readily apparent to one of ordinary skill in the art after review of the following figures and description. It is understood that, although exemplary embodiments are illustrated in the figures and described below, the principles of the present disclosure may be implemented using any number of techniques, whether currently known or not. Modifications, additions, or omissions may be made to the systems, apparatuses, and methods described herein without departing from the scope of the invention. The components of the systems and apparatuses may be integrated or separated. The operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set. It is intended that the claims and claim elements recited below do not invoke 35 U.S.C. § 112(f) unless the words “means for” or “step for” are explicitly used in the particular claim. The above-described embodiments, while including the preferred embodiment and the best mode of the invention known to the inventor at the time of filing, are given as illustrative examples only. It will be readily appreciated that many deviations may be made from the specific embodiments disclosed in this specification without departing from the spirit and scope of the invention. Accordingly, the scope of the invention is to be determined by the claims below rather than being limited to the specifically described embodiments above.

What is claimed is:

1. A semiconducting circuit, comprising:
(a) a silicon carbide crystal having a crystal surface;
(b) a semiconducting graphene layer disposed on the crystal surface;
(c) a dielectric layer disposed on the semiconducting graphene layer;
(d) at least one work function enhanced gate disposed on the dielectric layer on a side opposite from the semiconducting graphene layer; and
(e) at least one electrical conductor in electrical communication with the at least one work function enhanced gate.

2. The semiconducting circuit of claim 1, wherein the crystal face is a silicon terminated surface of the silicon carbide crystal.

3. The semiconducting circuit of claim 1, wherein the silicon carbide crystal comprises a hexagonal silicon carbide crystal.

4. The semiconducting circuit of claim 1, wherein the at least one work function enhanced gate comprises a material that has a work function that will locally cause the semiconducting graphene layer to become locally p-doped when a predetermined potential is applied thereto.

5. The semiconducting circuit of claim 1, wherein the at least one work function enhanced gate comprises a material that has a work function that will locally cause the semiconducting graphene layer to become locally n-doped when a predetermined potential is applied thereto.

6. The semiconducting circuit of claim 1, wherein the at least one work function enhanced gate comprises a material that has a work function that will locally cause the semiconducting graphene layer to non-conducting when a predetermined potential is applied thereto.

7. The semiconducting circuit of claim 1, wherein the at least one work function enhanced gate comprises a metal.

8. The semiconducting circuit of claim 1, wherein the at least one work function enhanced gate comprises a semiconductor.

9. The semiconducting circuit of claim 1, wherein the dielectric layer is at least partially patterned.

10. The semiconducting circuit of claim 1, further comprising a non-conducting layer disposed on the at least one work function enhanced gate, wherein the at least one electrical conductor comprises:
(a) a lateral electrical interconnect; and
(b) a through-via vertical conductor electrically coupled to the lateral electrical interconnect and in electrical communication with the work function enhanced gate.

11. A method of making a semiconducting circuit, comprising the steps of:
(a) forming a semiconducting graphene layer on a selected crystal face of a silicon carbide crystal;
(b) applying a dielectric layer to the semiconducting graphene layer;
(c) applying at least one work function enhanced gate to the dielectric layer;
(d) coupling the at least one work function enhanced gate to an electrical conductor.

12. The method of claim 11, wherein the step of forming a semiconducting graphene layer comprises annealing the silicon carbide crystal at a high temperature.

13. The method of claim 11, wherein the step of applying a dielectric layer is achieved using atomic layer deposition.

14. The method of claim 11, further comprising the step of disposing a non-conducting layer on the at least one work function enhanced gate, wherein the step of coupling the at least one work function enhanced gate to an electrical conductor comprises:
(a) generating a via through the non-conducting layer;
(b) coupling a vertical conductor to the at least one work function enhanced gate through the via and coupling the vertical conductor to the electrical conductor.

15. The method of claim 11, further comprising the step of patterning the dielectric layer.

16. The method of claim 11, wherein the crystal face is a silicon terminated surface of the silicon carbide crystal.

17. The method of claim 11, wherein the silicon carbide crystal comprises a hexagonal silicon carbide crystal.

18. The method of claim 11, wherein the at least one work function enhanced gate comprises a material that has a work function that will locally cause the semiconducting graphene layer to become locally p-doped when a predetermined potential is applied thereto.

19. The method of claim 11, wherein the at least one work function enhanced gate comprises a material that has a work function that will locally cause the semiconducting graphene layer to become locally n-doped when a predetermined potential is applied thereto.

20. The method of claim 11, wherein the at least one work function enhanced gate comprises a material that has a work function that will locally cause the semiconducting graphene layer to non-conducting when a predetermined potential is applied thereto.

21. The method of claim 11, wherein the at least one work function enhanced gate comprises a metal.

22. The method of claim 11, wherein the at least one work function enhanced gate comprises a semiconductor.
